(19) United States
(12) Patent Application Publication
(10) Pub. No.: US 2025/0344598 A1
(43) Pub. Date: Nov. 6, 2025

(54) DEPOSITION MASK AND DEPOSITION EQUIPMENT INCLUDING THE DEPOSITION MASK

(71) Applicant: Samsung Display Co., LTD., Yongin-si (KR)

(72) Inventors: Jeong Kuk KIM, Yongin-si (KR); Duck Jung LEE, Yongin-si (KR); Ji Hyun JUNG, Yongin-si (KR); Jun Ho JO, Yongin-si (KR)

(21) Appl. No.: 19/013,283

(22) Filed: Jan. 8, 2025

(30) Foreign Application Priority Data
May 3, 2024 (KR) 10-2024-0059330

(51) Int. Cl. H10K 71/16; C23C 16/04; H01L 21/02; H10K 59/12

(52) U.S. Cl. CPC H10K 71/166; C23C 16/042; H01L 21/02639; H10K 59/1201

(57) ABSTRACT

A deposition mask and deposition equipment including the deposition mask are provided. The deposition mask includes a substrate comprising a plurality of cell regions and a lip region dividing the plurality of cell regions, a mask membrane disposed on the plurality of cell regions of the substrate, a first line and a second line disposed on the lip region of the substrate, wherein the first line and the second line extend between neighboring cell regions of the plurality of cell regions, a first pad configured to provide a voltage of a first value to the first line from the outer edge of the substrate, and a second pad configured to provide a voltage of a second value to the second line from the outer edge of the substrate.

This application claims priority to Korean Patent Application No. 10-2024-0059330, filed on May 3, 2024, and all the benefits accruing therefrom under 35 U.S.C. § 119, the content of which in its entirety is herein incorporated by reference.

### BACKGROUND

### 1. Technical Field

The present disclosure relates to a deposition mask and deposition equipment including the deposition mask.

### 2. Description of the Related Art

Wearable devices have been developed in the form of glasses or a helmet in which a focus is formed at a distance close to a user's eyes. For example, a wearable device may be a head mounted display (HMD) device or AR glasses. Such a wearable device may provide an augmented reality (hereinafter, referred to as “AR”) screen or a virtual reality (hereinafter, referred to as “VR”) screen to a user.

Some wearable devices such as, for example, the HMD device or the AR glasses may require a display specification of approximately 3000 PPI (pixels per inch) or more such that a user may use the wearable devices for a long time without dizziness. To this end, organic light-emitting diode on silicon (OLEDoS) technology supportive of providing a high-resolution small organic light-emitting display device has emerged. Organic light-emitting diode on silicon (OLEDoS) technology is technology which includes disposing an organic light-emitting diode (OLED) on a semiconductor wafer substrate on which a complementary metal oxide semiconductor (CMOS) is disposed.

In order to manufacture a high-resolution display panel of approximately 3000 PPI or more, a high-resolution deposition mask may be implemented. As a deposition mask for manufacturing OLEDoS display panels, a mask in which an inorganic film is deposited on a silicon substrate and the deposited inorganic film is patterned to form a mask membrane is being studied. However, in some cases, a gap between the mask and the deposition surface of the deposition substrate may increase due to the weight of the mask membrane formed of an inorganic film. The gap may result in shadow defects or color mixing defects.

### SUMMARY

Aspects of the present disclosure provide a deposition mask capable of reducing shadow defects or color mixing defects by reducing the gap between a deposition substrate and a mask, and deposition equipment including the deposition mask.

According to an aspect of the present disclosure, a deposition mask includes a substrate including a plurality of cell regions and a lip region dividing the plurality of cell regions, a mask membrane disposed on the plurality of cell regions of the substrate, a first line and a second line disposed on the lip region of the substrate, wherein the first line and the second line extend between neighboring cell regions of the plurality of cell regions, a first pad configured to provide a voltage of a first value to the first line from the outer edge of the substrate, and a second pad configured to provide a voltage of a second value to the second line from the outer edge of the substrate.

In an embodiment, the mask membrane includes an inorganic film.

In an embodiment, each of the first line and the second line are disposed on the substrate and extend in a first direction on the substrate.

In an embodiment, the first line and the second line are disposed such that the first line and the second line are parallel to each other between the neighboring cell regions.

In an embodiment, each of the first line and the second line extend in a straight line when the substrate is viewed on a plane.

In an embodiment, each of the first line and the second line extend according to an uneven shape when the substrate is viewed on a plane.

In an embodiment, the deposition mask further including an insulating film disposed between the substrate and each of the first line and the second line.

In an embodiment, the insulating film includes an inorganic film.

In an embodiment, the substrate is a silicon substrate.

In an embodiment, based on voltage of a first value applied to the first line and voltage of a second value applied to the second line, the first line and the second line are configured to generate an electrostatic force associated with chucking deposition equipment.

According to an aspect of the present disclosure, deposition equipment includes a deposition source, and a mask disposed between the deposition source and a deposition substrate, wherein the mask includes a substrate including a plurality of cell regions and a lip region dividing the plurality of cell regions, a mask membrane disposed on the plurality of cell regions of the substrate, a first line and a second line disposed on the lip region of the substrate, wherein the first line and the second line extend between neighboring cell regions of the plurality of cell regions, a first pad configured to provide a voltage of a first value to the first line from the outer edge of the substrate, and a second pad configured to provide a voltage of a second value to the second line from the outer edge of the substrate.

In an embodiment, the mask membrane includes an inorganic film.

In an embodiment, each of the first line and the second line are disposed on the substrate and extend in a first direction on the substrate.

In an embodiment, the first line and the second line are disposed such that the first line and the second line are parallel to each other between the neighboring cell regions.

In an embodiment, each of the first line and the second line extend in a straight line when the substrate is viewed on a plane.

In an embodiment, each of the first line and the second line extend according to an uneven shape when the substrate is viewed on a plane.

In an embodiment, the deposition equipment further includes an insulating film disposed between the substrate and each of the first line and the second line.

In an embodiment, the insulating film includes an inorganic film.

In an embodiment, the substrate is a silicon substrate.

According to an aspect of the present disclosure, an electronic device may comprise a display device manufactured using a deposition mask and configured to provide an image, a processor configured to provide an image data signal to the display device, a memory configured to store a data information for operation, and a power module configured to generate power, wherein the deposition mask comprises a substrate including a plurality of cell regions and a lip region dividing the plurality of cell regions, a mask membrane disposed on the plurality of cell regions of the substrate, a first line and a second line disposed on the lip region of the substrate, wherein the first line and the second line extend between neighboring cell regions of the plurality of cell regions, a first pad configured to provide a voltage of a first value to the first line from the outer edge of the substrate, and a second pad configured to provide a voltage of a second value to the second line from the outer edge of the substrate.

In an embodiment, based on voltage of a first value applied to the first line and voltage of a second value applied to the second line, the first line and the second line are configured to generate an electrostatic force associated with chucking deposition equipment.

In accordance with the deposition mask and the deposition equipment including the deposition mask, shadow defects or color mixing defects may be reduced by reducing the gap between the deposition substrate and the mask.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view illustrating a display device according to an embodiment;

FIG. 2 is a block diagram illustrating a display device according to an embodiment;

FIG. 3 is an equivalent circuit diagram of a first sub-pixel according to an embodiment;

FIG. 4 is a layout diagram illustrating an example of a display panel according to an embodiment;

FIGS. 5 and 6 are layout diagrams illustrating embodiments of the display area of FIG. 4;

FIG. 7 is a cross-sectional view illustrating an example of a display panel taken along line II-II′ of FIG. 5;

FIG. 8 is a perspective view illustrating a head mounted display according to an embodiment;

FIG. 9 is an exploded perspective view illustrating an example of the head mounted display of FIG. 8;

FIG. 10 is a perspective view illustrating a head mounted display according to an embodiment;

FIG. 11 is a perspective view of a mask according to an embodiment;

FIG. 12 is a schematic plan view of a mask according to an embodiment;

FIG. 13 is a plan view of a mask illustrating electrostatic lines according to an embodiment;

FIG. 14 is a cross-sectional view illustrating an example of the mask cut along line A-B of FIG. 13;

FIGS. 15 to 17 are cross-sectional views illustrating a method of manufacturing a mask according to an embodiment;

FIG. 18 is a plan view of a mask illustrating electrostatic lines according to another embodiment;

FIG. 19 is a cross-sectional view illustrating another example of the mask cut along line A-B of FIG. 18; and

FIG. 20 is a configuration diagram schematically illustrating deposition equipment according to an embodiment.

FIG. 21 is a block diagram of an electronic device according to one embodiment of the present disclosure.

FIG. 22 is a schematic diagram of an electronic device according to various embodiments of the present disclosure.

### DETAILED DESCRIPTION

Embodiments supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will filly convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the present invention. Similarly, the second element could also be termed the first element.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

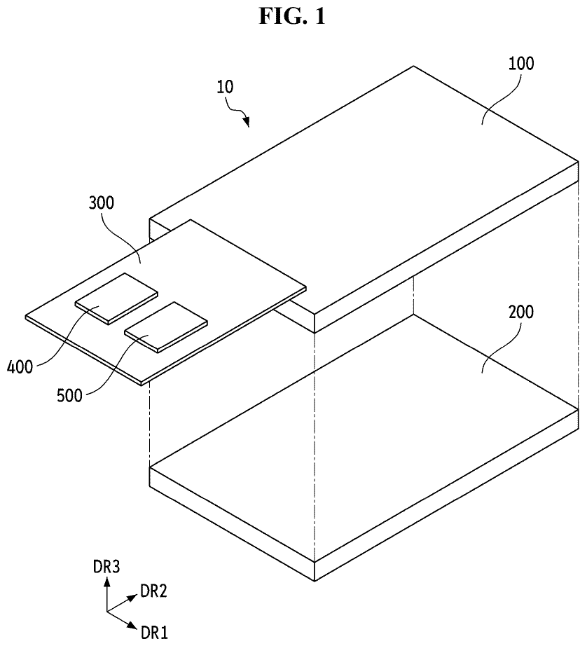

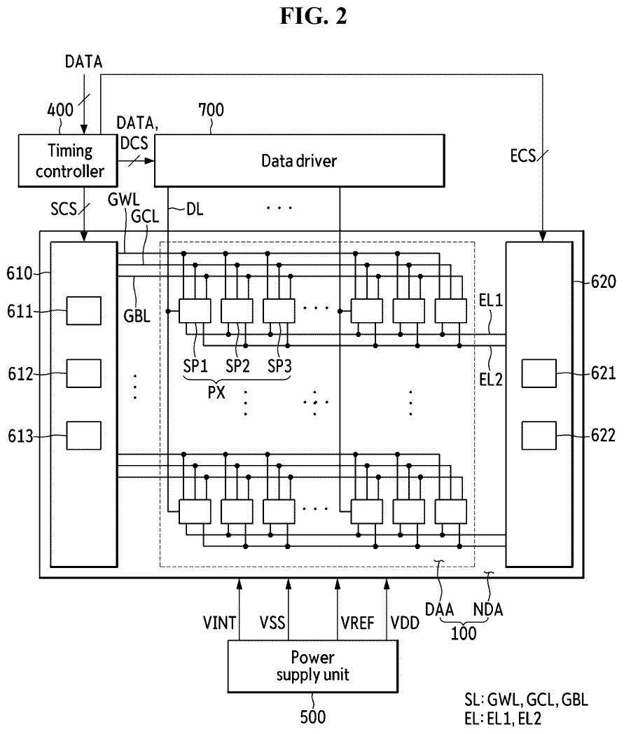

FIG. 1 is an exploded perspective view illustrating a display device according to an embodiment. FIG. 2 is a block diagram illustrating a display device according to an embodiment.

Referring to FIGS. 1 and 2, a display device 10 according to an embodiment is a device displaying a moving image or a still image. The display device 10 according to an embodiment may be applied to portable electronic devices such as, for example, a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. Alternatively, the display device 10 according to an embodiment may be applied to a smart watch, a watch phone, a head mounted display (HMD) for implementing virtual reality and augmented reality, and the like.

The display device 10 according to an embodiment includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but embodiments of the present disclosure are not limited thereto.

The display panel 100 includes a display area DAA displaying an image and a non-display area NDA not displaying an image as illustrated in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

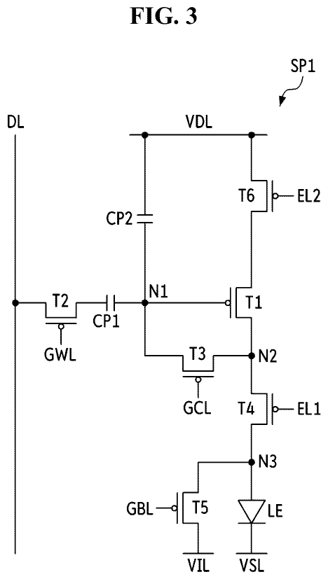

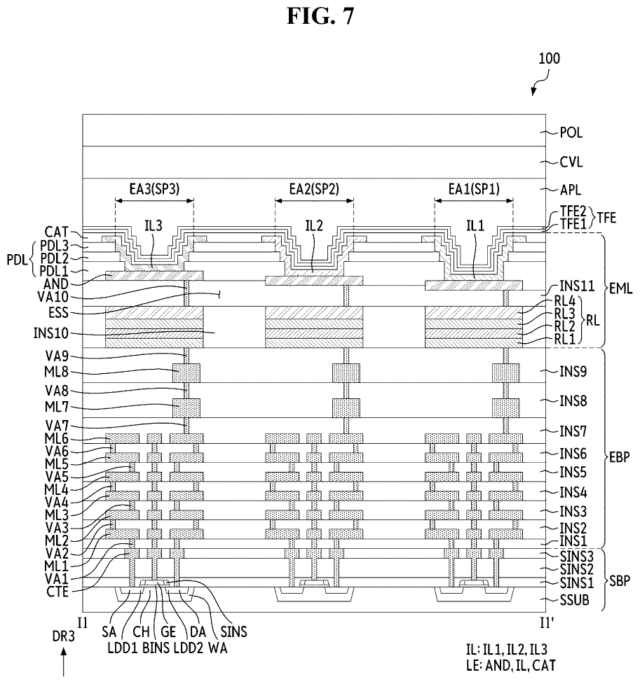

The plurality of pixels PX include a plurality of sub-pixels SP1, SP2, and SP3. The plurality of sub-pixels SP1, SP2, and SP3 may include a plurality of pixel transistors as illustrated in FIG. 3, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The non-display area NDA includes a scan driver 610, an emission driver 620, and a data driver 700.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS. Although it is illustrated in FIG. 2 that the scan driver 610 is disposed on the left side of the display area DAA and the emission driver 620 is disposed on the right side of the display area DAA, embodiments of the present disclosure are not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on a surface of the display panel 100, for example, on the rear surface of the display panel 100. The heat dissipation layer 200 serves to dissipate heat generated from the display panel 100. The heat dissipation layer 200 may include a metal layer such as, for example, graphite, silver (Ag), copper (Cu), or aluminum (Al) having high thermal conductivity.

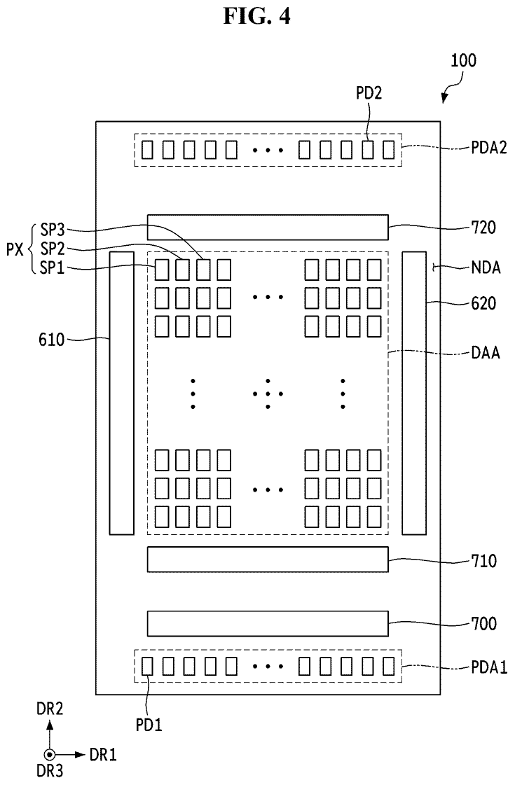

The circuit board 300 may be electrically connected to a plurality of first pads PD1 (see FIG. 4) of a first pad portion PDA1 (see FIG. 4) of the display panel 100 by using a conductive adhesive member such as, for example, an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data DATA and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to a surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, similarly to the scan driver 610, the emission driver 620, and the data driver 700, each of the timing control circuit 400 and the power supply circuit 500 may be disposed in the non-display area NDA of the display panel 100. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is an equivalent circuit diagram of a first sub-pixel according to an embodiment.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but embodiments of the present disclosure are not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode of the first transistor T1 according to a voltage applied to the gate electrode of the first transistor T1. The first transistor T1 includes a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that illustrated in FIG. 3. For example, the number of transistors and the number of capacitors of the first sub-pixel SP1 are not limited to those illustrated in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to an embodiment.

Referring to FIG. 4, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, embodiments of the present disclosure are not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board formed of a rigid material or a flexible printed circuit board formed of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

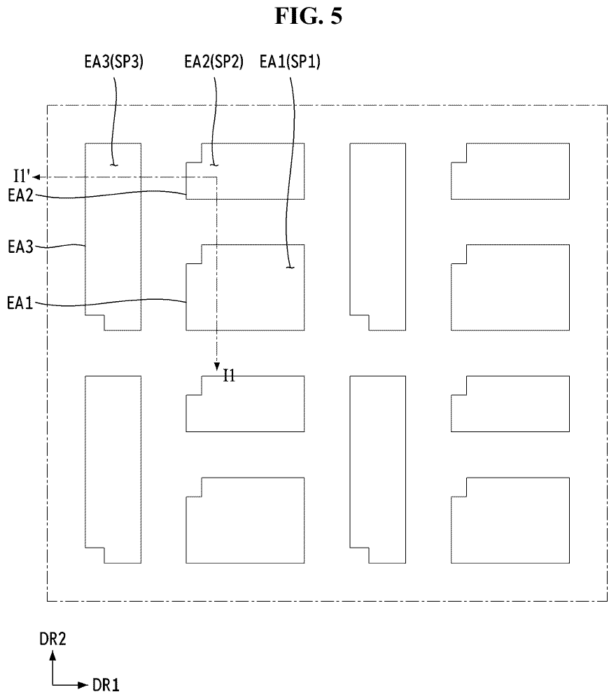

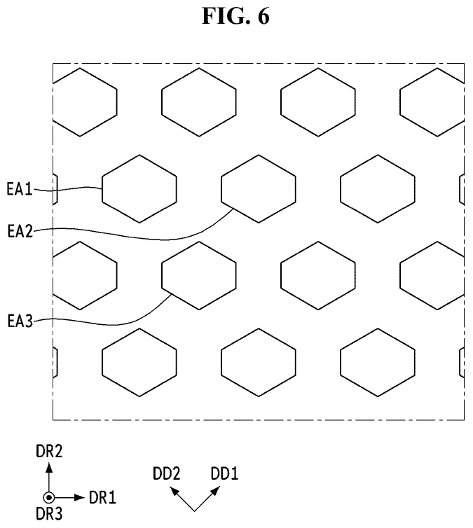

FIGS. 5 and 6 are layout diagrams illustrating embodiments of the display area of FIG. 4.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in a plan view.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as illustrated in FIGS. 5 and 6, but embodiments of the present disclosure are not limited thereto. The first emission area EA1, the second emission area EA2, and the third emission area EA3 may have a polygonal shape other than a hexagon, a circular shape, an elliptical shape, or an atypical shape in a plan view.

As illustrated in FIG. 5, in each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. In some aspects, the second emission area EA2 and the third emission area EA3 may be adjacent to each other in the first direction DR1. The area of the first emission area EA1, the area of the second emission area EA2, and the area of the third emission area EA3 may be different.

Alternatively, as illustrated in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

In the examples of FIGS. 5 and 6, each of the plurality of pixels PX includes three emission areas EA1, EA2, and EA3, but embodiments of the present disclosure are not limited thereto. That is, each of the plurality of pixels PX may include four emission areas.

In some aspects, the layout of the emission areas of the plurality of pixels PX is not limited to those illustrated in FIGS. 5 and 6. For example, the emission areas of the plurality of pixels PX may be disposed in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged as illustrated in FIG. 6.

FIG. 7 is a cross-sectional view illustrating an example of a display panel taken along line II-II′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. In an example in which the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, such that punch-through and hot carrier phenomena that might be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOx)-based inorganic film, but embodiments of the present disclosure are not limited thereto.

A second semiconductor insulating film SINS2 may be disposed on the first semiconductor insulating film SINS1. The second semiconductor insulating film SINS2 may be formed of a silicon oxide (SiOx)-based inorganic film, but embodiments of the present disclosure are not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy thereof.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but embodiments of the present disclosure are not limited thereto.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS9. In some aspects, the light-emitting element backplane EBP includes a plurality of insulating films INS2 to INS8 disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first sub-pixel SP1 illustrated in FIG. 3. For example, the first to sixth transistors T1 to T6 are formed in the semiconductor backplane SBP (e.g., are not formed in portions different from the semiconductor backplane SBP), and the connection of the first to sixth transistors T1 to T6 and the first and second capacitors C1 and C2 is accomplished through the first to eighth conductive layers ML1 to ML8. In some aspects, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy thereof. The first to eighth vias VA1 to VA8 may be formed of substantially the same material. First to eighth insulating films INS1 to INS8 may be formed of a silicon oxide (SiOx)-based inorganic film, but embodiments of the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be disposed on the eighth insulating film INS8 and the eighth conductive layer ML8. The ninth insulating film INS9 may be formed of a silicon oxide (SiOx)-based inorganic film, but embodiments of the present disclosure are not limited thereto.

Each of the ninth vias VA9 may penetrate the ninth insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy thereof. The thickness of the ninth via VA9 may be approximately 16500 Å.

The display element layer EML may be disposed on the light-emitting element backplane EBP. The display element layer EML may include light-emitting elements LE each including a reflective electrode layer RL, tenth and eleventh insulating films INS10 and INS11, a tenth via VA10, the first electrode AND, a light-emitting stack IL, and a second electrode CAT; and a pixel defining film PDL.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as illustrated in FIG. 7.

Each of the first reflective electrodes RL1 may be disposed on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy thereof. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy thereof. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy thereof. For example, the third reflective electrodes RL3 may include titanium nitride (TiN).

Each of the fourth reflective electrodes RL4 may be disposed on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy thereof. For example, the fourth reflective electrodes RL4 may include titanium (Ti).

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be formed of a silicon oxide (SiOx)-based inorganic film, but embodiments of the present disclosure are not limited thereto.

The eleventh insulating film INS11 may be disposed on the tenth insulating film INS10 and the reflective electrode layer RL. The eleventh insulating film INS11 may be formed of a silicon oxide (SiOx)-based inorganic film, but embodiments of the present disclosure are not limited thereto. The tenth insulating film INS10 and the eleventh insulating film INS11 may be an optical auxiliary layer through which light reflected by the reflective electrode layer RL passes, among light emitted from the light-emitting elements LE.

In order to match the resonance distance of the light emitted from the light-emitting elements LE in at least one of the first sub-pixel SP1, the second sub-pixel SP2, or the third sub-pixel SP3, the tenth insulating film INS10 or the eleventh insulating film INS11 may not be disposed under the first electrode AND. For example, the first electrode AND of the first sub-pixel SP1 may be directly disposed on the reflective electrode layer RL. The eleventh insulating film INS11 may be disposed under the first electrode AND of the second sub-pixel SP2. The tenth insulating film INS10 and the eleventh insulating film INS11 may be disposed under the first electrode AND of the third sub-pixel SP3.

In summary, the distance between the first electrode AND and the reflective electrode layer RL may be different in the first sub-pixel SP1, the second sub-pixel SP2, and the third sub-pixel SP3. That is, in order to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating film INS10 and the eleventh insulating film INS11 may be set in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. The present disclosure is not limited to the above examples.

In some aspects, although the tenth insulating film INS10 and the eleventh insulating film INS11 are illustrated in the present disclosure, a twelfth insulating film disposed under the first electrode AND of the first sub-pixel SP1 may be added. In this case, the eleventh insulating film INS11 and the twelfth insulating film may be disposed under the first electrode AND of the second sub-pixel SP2, and the tenth insulating film INS10, the eleventh insulating film INS11, and the twelfth insulating film may be disposed under the first electrode AND of the third sub-pixel SP3.

Each of the tenth vias VA10 may penetrate the tenth insulating film INS10 and/or the eleventh insulating film INS11 in the second sub-pixel SP2 and the third sub-pixel SP3 and may be connected to the exposed reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy thereof. The thickness of the tenth via VA10 in the second sub-pixel SP2 may be less than the thickness of the tenth via VA10 in the third sub-pixel SP3.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy thereof. For example, the first electrode AND of each of the light-emitting elements LE may be titanium nitride (TiN).

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but embodiments of the present disclosure are not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, such that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in accordance with one or more embodiments of the present disclosure, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL 1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

The light-emitting stack IL may include a plurality of intermediate layers. The light-emitting stack IL includes a first stack layer IL1, a second stack layer IL2, and a third stack layer IL3 that emit different lights. The first stack layer IL1, the second stack layer IL2, and the third stack layer IL3 are discontinuous between adjacent sub-pixels.

The first stack layer IL1 may have a structure in which a first hole transport layer, a first organic light-emitting layer that emits light of the first color, and a first electron transport layer are sequentially stacked. The first stack layer IL1 is disposed on the first electrodes AND and the pixel defining film PDL in the first emission area EA1 of the first sub-pixel SP1.

The second stack layer IL2 may have a structure in which a second hole transport layer, a second organic light-emitting layer that emits light of the third color, and a second electron transport layer are sequentially stacked. The second stack layer IL2 is disposed on the first electrodes AND and the pixel defining film PDL in the second emission area EA2 of the second sub-pixel SP2.

The third stack layer IL3 may have a structure in which a third hole transport layer, a third organic light-emitting layer that emits light of the second color, and a third electron transport layer are sequentially stacked. The third stack layer IL3 is disposed on the first electrodes AND and the pixel defining film PDL in the third emission area EA3 of the third sub-pixel SP3.

The second electrode CAT may be disposed on the third stack layer IL3 and the pixel defining film PDL. The second electrode CAT may be formed of a transparent conductive material (TCO) such as, for example, ITO or IZO that can transmit light or a semi-transmissive conductive material such as, for example, magnesium (Mg), silver (Ag), or an alloy of Mg and Ag. In an example in which the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) or aluminum oxide (AlOx), but embodiments of the present disclosure are not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the cover layer CVL. The organic film APL may be an organic film such as, for example, acrylic resin, epoxy resin, phenolic resin, polyamide resin, or polyimide resin.

The cover layer CVL may be disposed on the organic film APL. The cover layer CVL may be a glass substrate or a polymer resin.

The polarizing plate POL may be disposed on a surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but embodiments of the present disclosure are not limited thereto.

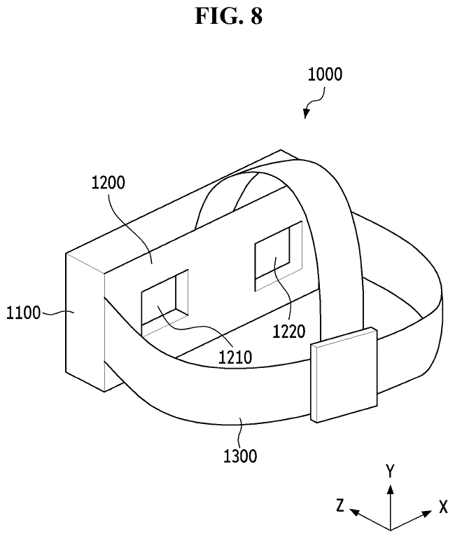

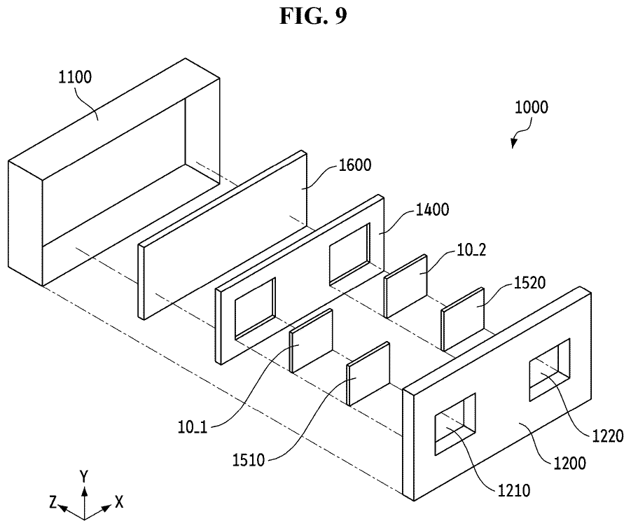

FIG. 8 is a perspective view illustrating a head mounted display according to an embodiment. FIG. 9 is an exploded perspective view illustrating an example of the head mounted display of FIG. 8.

Referring to FIGS. 8 and 9, a head mounted display 1000 according to an embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10 1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed such that the housing cover 1200 covers an open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

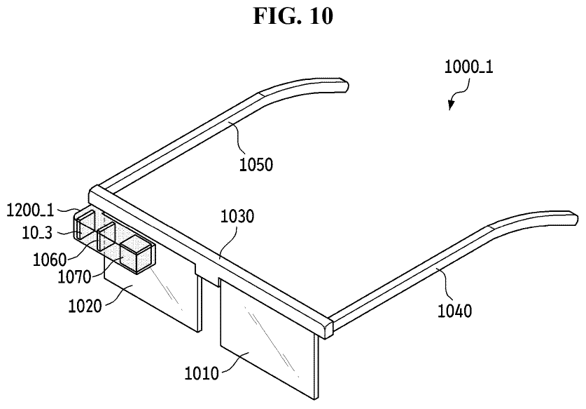

The head mounted band 1300 serves to secure the display device housing 1100 to the user's head such that the first eyepiece 1210 and the second eyepiece 1220 of the housing cover 1200 remain located on the user's left and right eyes, respectively. In an example in which the housing cover 1200 is implemented to be lightweight and compact, the head mounted display 1000 may be provided with, as illustrated in FIG. 10, an eyeglass frame instead of the head mounted band 1300.

In some aspects, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view illustrating a head mounted display according to an embodiment.

Referring to FIG. 10, a head mounted display 1000_1 according to an embodiment may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and the image may be provided to the user's right eye through the right eye lens 1020 after the optical path of the image is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but embodiments of the present disclosure are not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

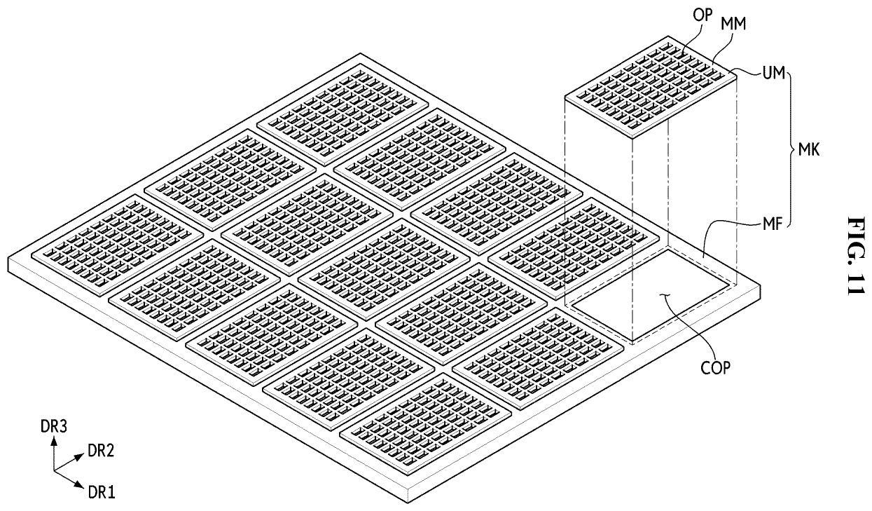

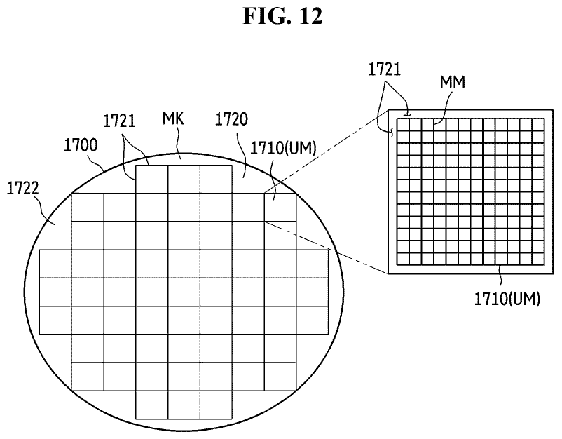

FIG. 11 is a perspective view of a mask according to an embodiment. FIG. 12 is a schematic plan view of a mask according to an embodiment. FIG. 11 illustrates a perspective view of a state in which one unit mask UM is separated from a plurality of unit masks. The mask according to an embodiment illustrated in FIGS. 11 and 12 may be used in the process of depositing at least a portion of the light-emitting stack IL described with reference to FIG. 7. For example, the light-emitting stack IL may be configured to emit a different color in each of the sub-pixels SP1, SP2, and SP3.

Referring to FIGS. 11 and 12, a mask MK according to an embodiment may be a shadow mask in which a mask membrane MM is disposed on a silicon substrate 1700. The mask MK according to an embodiment may be referred to as “silicon mask.”

According to an embodiment, the mask MK may include the silicon substrate 1700, and the mask membrane MM may be disposed on the silicon substrate 1700. The mask membrane MM may be disposed in cell regions 1710 arranged in a matrix form, and each cell region 1710 may be surrounded by a mask lip region 1721. The mask lip region 1721 may have a portion of the silicon substrate disposed therein, and may serve to support the mask membrane MM.

The mask membrane MM may be a part of the unit mask UM disposed in each of the plurality of cell regions 1710.

The silicon substrate 1700 may include the plurality of cell regions 1710 and a mask frame region 1720 excluding the plurality of cell regions 1710. The mask frame region 1720 may include the mask lip region 1721 surrounding each cell region 1710, and an outer frame region 1722 disposed at the outermost edge of the silicon substrate 1700. A mask frame MF may be disposed in the mask frame region 1720, and the mask frame MF may include a mask lip surrounding the cell region 1710.

The mask lip region 1721 may be a region that partitions the plurality of cell regions 1710. For example, the plurality of cell regions 1710 may be arranged in a matrix form, and the mask lip disposed in the mask lip region 1721 may be disposed to surround the outer edge of the mask membrane MM disposed in each cell region 1710.

A cell opening COP and the unit mask UM for masking at least a portion of the cell opening COP may be disposed in each of the plurality of cell regions 1710 of the silicon substrate 1700.

The plurality of cell openings COP may penetrate the mask frame MF along a thickness direction (e.g., the third direction DR3) of the mask MK. The plurality of cell openings COP may be formed by etching a portion of the silicon substrate 1700 from the rear direction.

Each unit mask UM may include the mask membrane MM, and the mask membrane MM may include a mask opening.

The mask opening of the mask membrane MM may be referred to as “hole” or “mask hole.” The mask openings may penetrate the unit masks UM along the thickness direction (e.g., the third direction DR3) of the mask MK.

One unit mask UM may be used in the deposition process of one display panel 100. In the present disclosure, the term “unit mask UM” may be replaced with a term such as a mask unit UM.

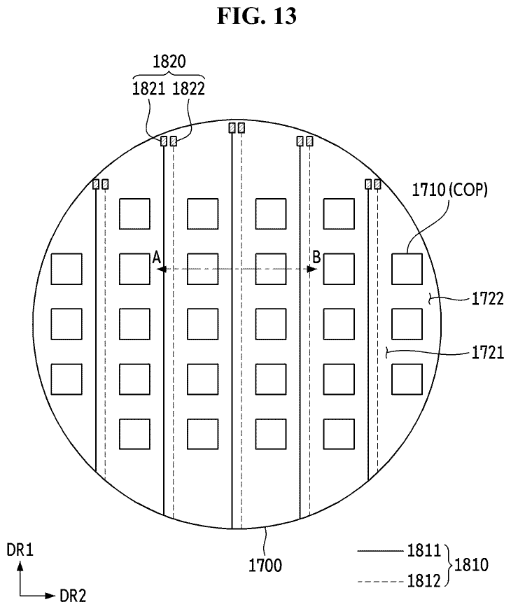

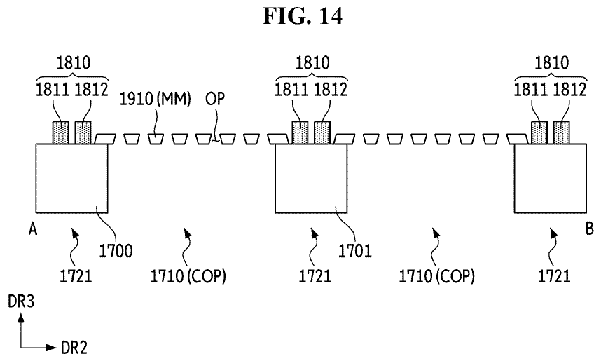

FIG. 13 is a plan view of a mask illustrating electrostatic lines according to an embodiment. FIG. 14 is a cross-sectional view illustrating an example of the mask cut along line A-B of FIG. 13. For example, at least a portion of the mask illustrated in each of FIGS. 13 and 14 may be similar to the mask illustrated in FIG. 12.

Referring to FIGS. 13 and 14, a mask MK according to an embodiment includes a substrate 1700, and the substrate 1700 includes a plurality of cell regions 1710 and a lip region 1721 dividing the plurality of cell regions 1710. For example, a mask lip region 1721 may divide the plurality of cell regions 1710 into groups of cell regions 1710. Here, the substrate 1700 may be a silicon substrate.

A mask membrane MM may be disposed in the plurality of cell regions 1710, and a cell opening COP exposing the mask membrane MM from the lower surface of the substrate 1700 may be formed.

The cell opening COP may be formed by etching a portion of the substrate 1700. The rest of the area of the substrate 1700 remaining after the process of forming the cell opening COP may become a mask frame region 1720 (see FIG. 12). The mask frame region 1720 may be divided into a mask lip region 1721 surrounding each cell region 1710 and an outer frame region 1722 disposed on the outermost edge of the silicon substrate 1700. Here, a mask lip 1701 (see FIG. 14) surrounding the cell region 1710 is disposed in the mask lip region 1721, and electrostatic lines 1810 are disposed on the mask lip 1701.

The mask membrane MM may include an inorganic film 1910 (see FIG. 14) including a plurality of openings OP. The inorganic film 1910 may contain at least one material selected from silicon (Si), silicon nitride (SiNx), silicon oxynitride (SiON), silicon oxide (SiOx), titanium oxide (TiOx), amorphous silicon (a-Si), and aluminum oxide (AlOx).

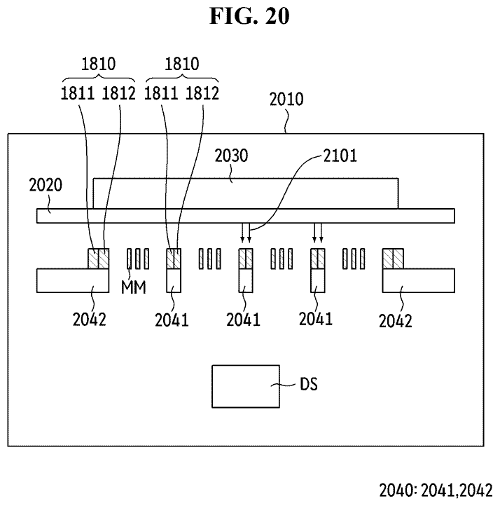

The electrostatic line 1810 may be or be part of an electrostatic chuck. For example, the electrostatic line 1810 may be disposed as an electrostatic chuck (or as part of an electrostatic chuck) on the lip region 1721 of the substrate 1700. The electrostatic line 1810 may include at least one line for generating electrostatic force. The electrostatic line 1810 may chuck (e.g., electrostatically attract or fix by the electrostatic force) or dechuck a deposition substrate 2020 (see FIG. 20) during the deposition process. In an example in which a specified voltage is applied to the electrostatic line 1810, the electrostatic line 1810 chucks the deposition substrate 2020. If a specified voltage is not applied to the electrostatic line 1810, the electrostatic line 1810 may dechuck the deposition substrate 2020.

According to an embodiment, the electrostatic line 1810 may be of a bipolar type or a monopolar type. In an example in which the electrostatic line 1810 is a bipolar type, the electrostatic line 1810 may include two lines, that is, a first line 1811 and a second line 1812. In an example in which the electrostatic line 1810 is a monopolar type, the electrostatic line 1810 may include one line.

Hereinafter, description will mainly focus on the electrostatic line 1810 being a bipolar type, but embodiments of the present disclosure are not limited thereto.

According to an embodiment, the electrostatic line 1810 may include a first line 1811 and a second line 1812. In FIG. 13, the first lines 1811 are displayed as solid lines and the second lines 1812 are displayed as dotted lines. As illustrated, the first line 1811 and the second line 1812 extend in a direction, between neighboring cell regions 1710. For example, the first line 1811 and the second line 1812 may cross an area located between the neighboring cell regions 1710. For example, each of the first line 1811 and the second line 1812 are disposed on the substrate and extend in a first direction DR1.

According to an embodiment, the first line 1811 and the second line 1812 are disposed such that the first line 1811 and the second line 1812 are parallel to each other between the neighboring cell regions 1710. The first line 1811 and the second line 1812 may be disposed such that the first line 1811 and the second line 1812 are spaced apart between the neighboring cell regions 1710.

According to an embodiment, the mask MK may further include a pad portion 1820 providing a voltage to the electrostatic line 1810 from the outer edge of the substrate 1700. The pad portion 1820 includes a first pad 1821 configured to provide a voltage of positive polarity to the first line 1811 from the outer edge of the substrate 1700 and a second pad 1822 configured to provide voltage of negative polarity to the second line 1812 from the outer edge of the substrate 1700. In an example, deposition equipment described herein may apply or provide the voltage of positive polarity to the first line 1811 via the first pad 1821, and the deposition equipment may apply or provide the voltage of negative polarity to the second line 1812 via the second pad 1822. For example, the first pad 1821 and the second pad 1822 are disposed in any one region of the outer frame region 1722.

The first pad 1821 is configured to receive the voltage of positive polarity from the outside and supply the received voltage of positive polarity to the first line 1811. The second pad 1822 is configured to receive the voltage of negative polarity from the outside and supply the received voltage of negative polarity to the second line 1812.

In the present disclosure, the voltage of positive polarity may mean a voltage having relatively higher potential compared to the voltage of negative polarity. In the present disclosure, the voltage of negative polarity may mean a voltage having relatively lower potential compared to the voltage of positive polarity.

The voltage of positive polarity of the present disclosure may be referred to as terms such as, for example, “first voltage,” “high potential voltage”, “voltage of a first value,” and the like.

The voltage of negative polarity of the present disclosure may be referred to as terms such as, for example, “second voltage,” “low potential voltage”, “voltage of a second value,” and the like.

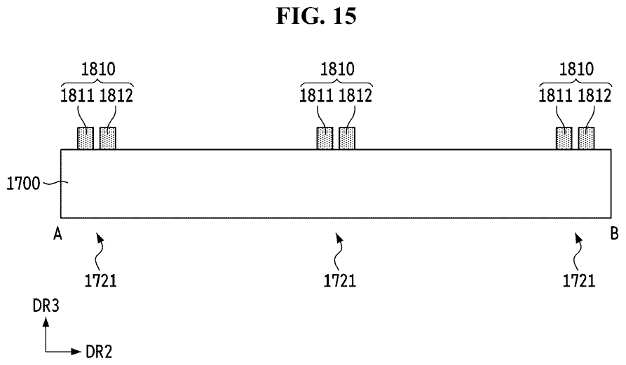

FIGS. 15 to 17 are cross-sectional views illustrating a method of manufacturing a mask according to an embodiment. For example, FIGS. 15 to 17 may be sequential examples of the manufacturing process of the mask according to an embodiment illustrated in FIG. 14. Hereinafter, referring to FIGS. 15 to 17, a manufacturing method of a mask according to an embodiment will be described.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 15, a substrate 1700 may be prepared. The substrate 1700 may be a silicon substrate. The substrate 1700 may be referred to as “body substrate” or “membrane substrate”, but embodiments of the present disclosure are not limited thereto.

In an example of preparing the substrate 1700, the method may include forming an electrostatic line 1810 on the substrate 1700. The electrostatic line 1810 includes a first line 1811 and a second line 1812, and is formed to correspond to a mask lip region 1721. The electrostatic line 1810 may be formed of any one of copper (Cu), aluminum (Al), tungsten (W), molybdenum (Mo), chromium (Cr), gold (Au), titanium (Ti), nickel (Ni), and neodymium (Nd), or an alloy thereof.

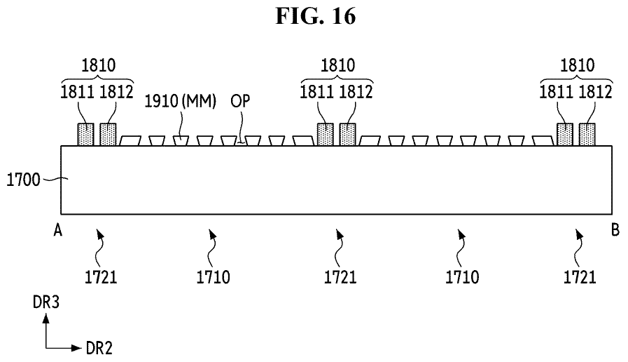

Referring to FIG. 16, after forming the electrostatic line 1810 on the substrate 1700, the method may include forming a mask membrane MM by using an inorganic film 1910. The inorganic film 1910 may include a single layer or multiple layers.

According to an embodiment, the inorganic film 1910 may include a single layer, and may contain at least one material selected from silicon (Si), silicon nitride (SiNx), silicon oxynitride (SiON), silicon oxide (SiOx), titanium oxide (TiOx), amorphous silicon (a-Si), and aluminum oxide (AlOx).

According to an embodiment, the inorganic film 1910 may include a first inorganic film and a second inorganic film as multiple layers. In this case, the first inorganic film may contain silicon oxide (SiOx), and the second inorganic film may contain silicon nitride (SiNx). However, the material of each of the first inorganic film and the second inorganic film are not limited thereto. For example, the material of each of the first inorganic film and the second inorganic film may contain at least one material selected from silicon (Si), silicon nitride (SiNx), silicon oxynitride (SiON), silicon oxide (SiOx), titanium oxide (TiOx), amorphous silicon (a-Si), and aluminum oxide (A1Ox).

After depositing the inorganic film 1910 on the substrate 1700, the method may include performing a patterning process of the inorganic film 1910 in association with forming a plurality of openings OP. The patterning process of the inorganic film 1910 may include a process of forming a photoresist pattern on the inorganic film 1910 and etching a portion of the inorganic film 1910 by using the photoresist pattern as a mask. The process of etching the inorganic film 1910 may include a wet etching process or a dry etching process.

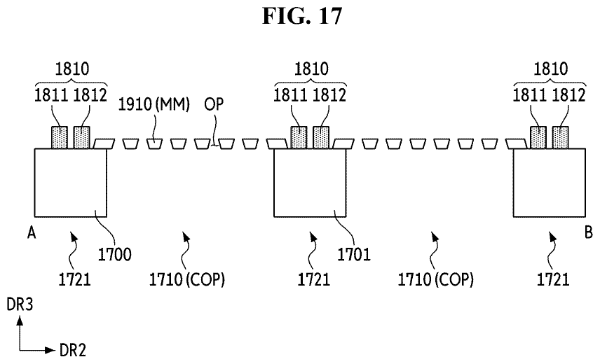

Referring to FIG. 17, after forming the mask membrane MM by using the inorganic film 1910, the method may include forming a cell opening COP. The method may include forming the cell opening COP by a process of etching a portion of the substrate 1700 in the rear direction of the substrate 1700.

The regions of the substrate remaining in the process of forming the cell opening COP become a mask frame region 1720 (see FIG. 12). The mask frame region 1720 may be divided into a mask lip region 1721 surrounding each cell region 1710 and an outer frame region 1722 disposed at the outermost edge of the silicon substrate 1700. Here, a mask lip 1701 surrounding the cell region 1710 is disposed in the mask lip region 1721, and an electrostatic line 1810 is disposed on the mask lip 1701.

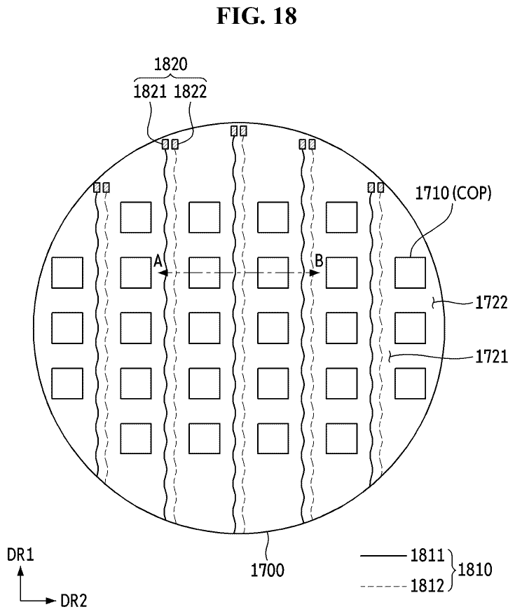

FIG. 18 is a plan view of a mask illustrating electrostatic lines according to another embodiment.

Unlike the embodiment of FIG. 13, the embodiment of FIG. 18 has a difference in that the electrostatic line 1810 has an uneven shape. Hereinafter, referring to FIG. 18, the differences from FIG. 13 will be described. Repeated descriptions of like elements are omitted for brevity. The characteristics not described in relation to FIG. 18 will be replaced with descriptions referring to FIG. 13.

Referring to FIG. 18, a mask MK according to an embodiment includes an electrostatic line 1810 including a first line 1811 and a second line 1812.

According to an embodiment, the first line 1811 and the second line 1812 are disposed such that the first line 1811 and the second line 1812 are parallel to each other between the neighboring cell regions 1710. The first line 1811 and the second line 1812 may be disposed such that the first line 1811 and the second line 1812 are spaced apart between the neighboring cell regions 1710.

According to an embodiment, each of the first line 1811 and the second line 1812 extends according to an uneven shape (e.g., a wavy line) when the substrate 1700 is viewed on a plane. Each of the first line 1811 and the second line 1812 extends in an uneven shape, thereby increasing the corresponding area (e.g., with respect to the second direction DR2) of the electrostatic line 1810 with respect to the deposition substrate 2020. For example, the corresponding area of the electrostatic line 1810 (e.g., with respect to the second direction DR2) with respect to the deposition substrate 2020 according to the embodiment of FIG. 18 is greater compared to the corresponding area of the electrostatic line 1810 with respect to the deposition substrate 2020 according to the embodiment of FIG. 13.

In the embodiment of FIG. 18, by increasing the corresponding area of the electrostatic line 1810 with respect to the deposition substrate 2020, the electrostatic line 1810 of the mask MK may more effectively chuck (e.g., electrostatically attract or fix) the deposition substrate 2020 and reduce the gap between the deposition substrate 2020 and the mask MK. In an example in which the gap between the deposition substrate 2020 and the mask MK is reduced, shadow defects may be reduced during the deposition process.

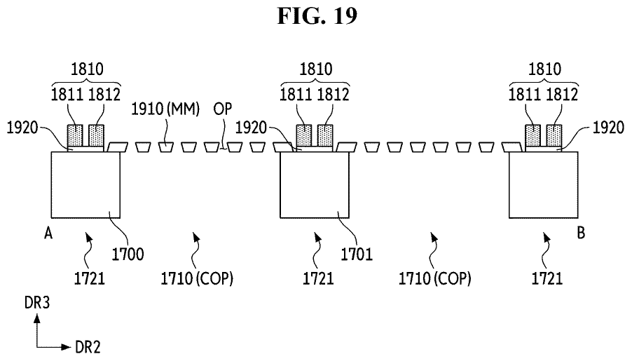

FIG. 19 is a cross-sectional view illustrating another example of the mask cut along line A-B of FIG. 18.

Unlike the embodiment of FIG. 14, the embodiment of FIG. 19 has a difference in that an insulating film is formed below the electrostatic line 1810. Hereinafter, referring to FIG. 19, the differences from FIG. 14 will be described. Repeated descriptions of like elements are omitted for brevity. The characteristics not described in relation to FIG. 19 will be replaced with descriptions referring to FIG. 14.

Referring to FIG. 19, a mask MK includes an electrostatic line 1810 including a first line 1811 and a second line 1812.

According to an embodiment, the first line 1811 and the second line 1812 are disposed such that the first line 1811 and the second line 1812 are parallel to each other between the neighboring cell regions 1710. The first line 1811 and the second line 1812 may be disposed such that the first line 1811 and the second line 1812 are spaced apart between the neighboring cell regions 1710.

According to an embodiment, an insulating film 1920 may be disposed below the first line 1811 and the second line 1812. For example, the mask MK further includes an insulating film 1920 disposed between the substrate and each of the first line 1811 and the second line 1812.

According to an embodiment, the insulating film 1920 includes an inorganic film. For example, the insulating film 1920 may be an inorganic film containing at least one material selected from silicon (Si), silicon nitride (SiNx), silicon oxynitride (SiON), silicon oxide (SiOx), titanium oxide (TiOx), amorphous silicon (a-Si), and aluminum oxide (AlOx).

The insulating film 1920 may prevent leakage current from the electrostatic line 1810 to a portion of the deposition equipment, for example, a chamber 2010 of FIG. 20 during the deposition process. The insulating film 1920 may include a material with high heat resistance and chemical stability. For example, the insulating film 1920 may include yttrium oxide, alumina, and the like.

FIG. 20 is a configuration diagram schematically illustrating deposition equipment according to an embodiment.

Referring to FIG. 20, the deposition equipment according to an embodiment includes a chamber 2010, the deposition source DS disposed inside the chamber 2010, the mask MK disposed between a deposition substrate 2020 and the deposition source DS inside the chamber 2010, and a mask support 2040 disposed between the deposition source DS and the mask MK and configured to support at least a portion of the mask MK.

According to an embodiment, the mask MK includes a substrate 1700 (see FIG. 12) including the plurality of cell regions 1710 (see FIG. 12) and the mask frame region 1720 (see FIG. 12) excluding the plurality of cell regions 1710, and the mask membrane MM disposed in each cell region 1710.

The deposition substrate 2020 illustrated in FIG. 20 may be the display panel 100 described with reference to FIGS. 1 to 10. Therefore, the description of the deposition substrate 2020 is replaced with the description of the display panel 100 with reference to FIGS. 1 to 10.

The mask MK illustrated in FIG. 20 may be a mask MK described with reference to FIGS. 13 to 19.

According to an embodiment, the mask MK includes an electrostatic line 1810 including a first line 1811 and a second line 1812. The electrostatic line 1810 may chuck or dechuck the deposition substrate 2020 during the deposition process. In an example in which a specified voltage is applied to the electrostatic line 1810, the electrostatic line 1810 may chuck the deposition substrate 2020 as illustrated with an arrow 2101 of FIG. 20. In an example in which a specified voltage is not applied to the electrostatic line 1810, the electrostatic line 1810 may dechuck the deposition substrate 2020.

The mask support 2040 may serve to support and fix the mask MK under the mask MK. For example, the mask support 2040 may include an electrostatic chuck. According to an embodiment, the mask support 2040 may include a first support region 2041 supporting the mask lip region 1721 and a second support region 2042 supporting the outer frame region 1722. However, the mask support 2040 may not support the mask lip region 1721, and for example, the first support region 2041 may be omitted.

The reference numeral 2030 illustrated in FIG. 20 is a fixing member 2030 for securing the deposition substrate 2020, which may include, for example, an electrostatic chuck.

The display device according to one embodiment of the present disclosure can be applied to various electronic devices. The electronic device according to the one embodiment of the present disclosure includes the display device described above, and may further include modules or devices having additional functions in addition to the display device.

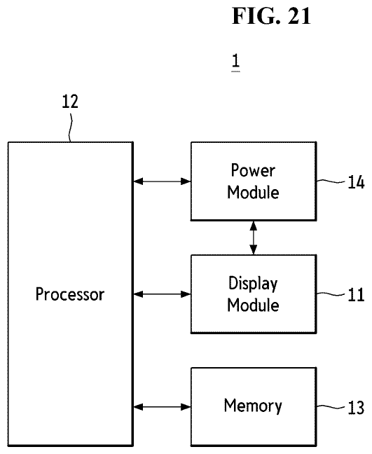

FIG. 21 is a block diagram of an electronic device according to one embodiment of the present disclosure.

Referring to FIG. 21, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

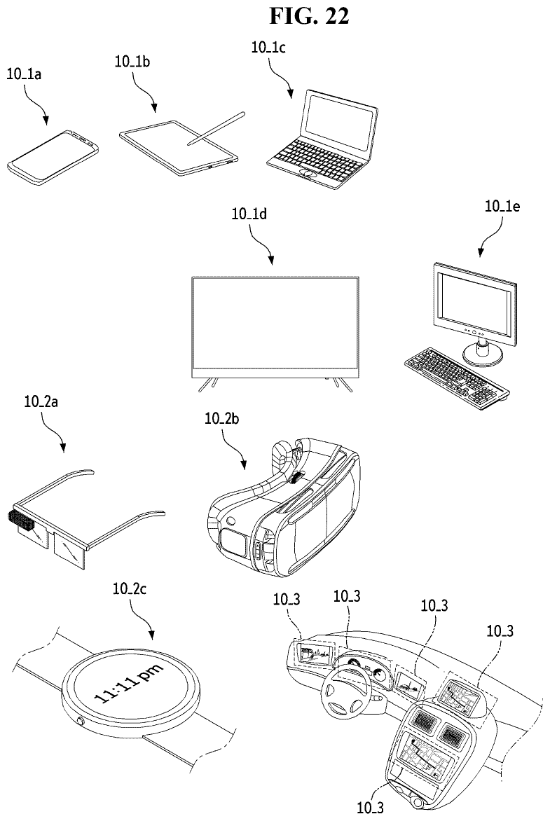

FIG. 22 is a schematic diagram of an electronic device according to various embodiments of the present disclosure.

Referring to FIG. 22, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the example embodiments without substantially departing from the principles of the present invention. Therefore, the disclosed example embodiments of the present disclosure are used in a generic and descriptive sense and not for purposes of limitation.

What is claimed is:

1. A deposition mask comprising:
a substrate comprising a plurality of cell regions and a lip region dividing the plurality of cell regions;
a mask membrane disposed on the plurality of cell regions of the substrate;
a first line and a second line disposed on the lip region of the substrate, wherein the first line and the second line extend between neighboring cell regions of the plurality of cell regions;
a first pad configured to provide a voltage of a first value to the first line from an outer edge of the substrate; and
a second pad configured to provide a voltage of a second value to the second line from the outer edge of the substrate.

2. The deposition mask of claim 1,
wherein the mask membrane comprises an inorganic film.

3. The deposition mask of claim 1,
wherein each of the first line and the second line are disposed on the substrate and extend in a first direction on the substrate.

4. The deposition mask of claim 3,
wherein the first line and the second line are disposed such that the first line and the second line are parallel to each other between the neighboring cell regions.

5. The deposition mask of claim 4,
wherein each of the first line and the second line extend in a straight line when the substrate is viewed on a plane.

6. The deposition mask of claim 4,
wherein each of the first line and the second line extend according to an uneven shape when the substrate is viewed on a plane.

7. The deposition mask of claim 4,
further comprising an insulating film disposed between the substrate and each of the first line and the second line.

8. The deposition mask of claim 7,
wherein the insulating film comprises an inorganic film.

9. The deposition mask of claim 1,
wherein the substrate is a silicon substrate.

10. The deposition mask of claim 1,
wherein, based on voltage of a first value applied to the first line and voltage of a second value applied to the second line, the first line and the second line are configured to generate an electrostatic force associated with chucking deposition equipment.

11. Deposition equipment comprising:
a deposition source; and
a mask disposed between the deposition source and a deposition substrate,
wherein the mask comprises:
a substrate comprising a plurality of cell regions and a lip region dividing the plurality of cell regions;
a mask membrane disposed on the plurality of cell regions of the substrate;
a first line and a second line disposed on the lip region of the substrate, wherein the first line and the second line extend between neighboring cell regions of the plurality of cell regions;
a first pad configured to provide a voltage of a first value to the first line from an outer edge of the substrate; and
a second pad configured to provide a voltage of a second value to the second line from the outer edge of the substrate.

12. The deposition equipment of claim 11,
wherein the mask membrane comprises an inorganic film.

13. The deposition equipment of claim 11,
wherein each of the first line and the second line are disposed on the substrate and extend in a first direction on the substrate.

14. The deposition equipment of claim 13,
wherein the first line and the second line are disposed such that the first line and the second line are parallel to each other between the neighboring cell regions.

15. The deposition equipment of claim 14,
wherein each of the first line and the second line extend in a straight line when the substrate is viewed on a plane.

16. The deposition equipment of claim 14,
wherein each of the first line and the second line extend according to an uneven shape when the substrate is viewed on a plane.

17. The deposition equipment of claim 14,
further comprising an insulating film disposed between the substrate and each of the first line and the second line.

18. The deposition equipment of claim 17,
wherein the insulating film comprises an inorganic film.

19. The deposition equipment of claim 11,
wherein the substrate is a silicon substrate.

20. The deposition equipment of claim 11,
wherein, based on voltage of a first value applied to the first line and voltage of second value applied to the second line, the first line and the second line are configured to generate an electrostatic force associated with chucking deposition equipment.

21. An electronic device, comprising:
a display device manufactured using a deposition mask and configured to provide an image;
a processor configured to provide an image data signal to the display device;
a memory configured to store a data information for operation; and
a power module configured to generate power,
wherein the deposition mask comprising:
a substrate comprising a plurality of cell regions and a lip region dividing the plurality of cell regions;
a mask membrane disposed on the plurality of cell regions of the substrate;
a first line and a second line disposed on the lip region of the substrate, wherein the first line and the second line extend between neighboring cell regions of the plurality of cell regions;
a first pad configured to provide a voltage of a first value to the first line from an outer edge of the substrate; and
a second pad configured to provide a voltage of a second value to the second line from the outer edge of the substrate.
